(19) United States
(12) Patent Application Publication
(10) Pub. No.: US 2009/0218950 A1
(43) Pub. Date: Sep. 3, 2009

(54) Single sheet film filter, method of manufacturing the same, and plasma display apparatus using the same

(76) Inventors: Chong-Gi Hong, Suwon-si (KR); Sung-Yong Lee, Suwon-si (KR); Jae-Young Park, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/320,886

(22) Filed: Feb. 6, 2009

(30) Foreign Application Priority Data
Feb. 29, 2008 (KR) 10-2008-0019096

(51) Int. Cl. H01J 1/52; H05K 9/00; B44C 1/22; B32B 37/00

(52) U.S. Cl. 315/85; 361/816; 216/13; 156/60

(57) ABSTRACT

A single sheet film filter and a manufacturing method thereof and a plasma display apparatus with the single sheet film filter capable of preventing ground problems, securing ground resistance, and reducing ground processing time. This single sheet film filter includes a conductive layer for shielding EMI arranged on one surface of a transparent base film and having a ground portion at an edge region on the base film and a hard coating layer covering the conductive layer in which the ground portion is exposed through a plurality of apertures in a stripe shape formed in the hard coating layer.

### CLAIM OF PRIORITY

This application makes reference to, incorporates the same herein, and claims all benefits accruing under 35 U.S.C. §119 from an application for SINGLE SHEET FILM FILTER, METHOD OF MANUFACTURING THE SAME, AND PLASMA DISPLAY APPARATUS WITH USING THE SAME earlier filed in the Korean Intellectual Property Office on 29 Feb. 2008 and there duly assigned Serial No. 10-2008-0019096.

### BACKGROUND OF THE INVENTION

1. Field of the Invention

The present invention relates to a single sheet film filter, a method of manufacturing the same, and a plasma display apparatus using the same capable of securing ground resistance ability and realizing light weight, thinness, and low-cost by using a laser etching process in order to expose a ground portion covered with a hard coating layer.

2. Description of the Related Art

A plasma display apparatus using a plasma display panel (PDP) is a flat panel display apparatus displaying an image using a gas discharge phenomenon. The plasma display apparatus is superior in various display characteristics such as brightness, contrast, afterimage, viewing angle, etc, as compared to an existing cathode-ray tube (CRT) display apparatus. Also, the plasma display apparatus can display large image on the screen so that it has been spotlighted as a next-generation large flat panel display apparatus.

The above-mentioned plasma display apparatus uses a high voltage and a high frequency in a driving process, and thus a number of electromagnetic waves are discharged to a front surface of the panel. Also, the plasma display apparatus discharges near infrared rays (NIR) induced from inert gas such as neon (Ne), xenon (Xe), etc. Such a near infrared ray has a wavelength in close proximity to a wavelength of a remote controller of a home appliance, so that it can cause malfunction of the home appliance. The plasma display apparatus also has a problem that glaringness is generated or contrast is lowered since glass on the front surface of the panel reflects external light. For these reasons, most plasma display apparatuses have solved the above-mentioned problems by installing a tempered glass filter or a film filter on the front surface of the panel.

However, using the tempered glass filter or the film filter increases weight or process cost of a product and reduces yield of the product due to addition of components.

For example, in the plasma display apparatus adopting the tempered glass filter, a refraction phenomenon of light is generated due to difference in materials between a front substrate of the panel and the tempered glass. Such a refraction phenomenon causes a problem that an image is doubly reflected. Also, the tempered glass filter has thickness more than about 3 mm in order to bear external impact, so that weight and cost of the plasma display apparatus are increased.

In the plasma display apparatus adopting a separately fabricated film filter, the film filter should be attached to the front surface of the panel in order that an electromagnetic wave shielding layer of the film filter is entirely transferred on the front surface of the panel. Also, the electromagnetic wave shielding layer in the attached film filter should be suitably coupled to a ground terminal of the panel. Therefore, a complicated and precise process is required that increases the cost and reduces the yield of the product are inevitable.

As described above, the film filter is suitable for being applied to the plasma display apparatus in view of light weight, thinness, low cost, as compared to the tempered glass filter. However, there is a need for improvement of a high cost structure for the electromagnetic wave shielding layer and ground processing, etc.

The above information disclosed in this Description of the Related Art section is only for enhancement of understanding of the background of the invention and therefore it may contain information that does not form the prior art that is already known to a person of ordinary skill in the art.

### SUMMARY OF THE INVENTION

Accordingly, it is an object of the present invention to provide a manufacturing method of a single sheet film filter using a laser etching process in order to expose a ground portion covered with a hard coating layer.

It is another object of the present invention to provide a single sheet film filter having a ground portion exposure pattern structure capable of reducing a ground defect due to laser over-etching and securing a desired ground resistance.

It is another object of the present invention to provide a plasma display apparatus capable of securing ground ability of a filter and reducing cost of a product by using the single sheet film filter.

According to one aspect of the present invention, there is provided a single sheet film filter including: a conductive layer for shielding EMI arranged on one surface of a transparent base film and having a ground portion at an edge region on the base film; and a hard coating layer covering the conductive layer; wherein the ground portion is exposed through a plurality of apertures in a stripe shape formed in the hard coating layer.

An average interval between the plurality of apertures is selected in the range of 0.02 mm to 0.2 mm.

The plurality of apertures include a stripe shape extended in at least one direction of a first direction, or a second direction perpendicular to the first direction, or an oblique direction different from the first and second directions on a plane.

Exemplarily, the plurality of apertures are installed on at least two of four sides, i.e. up, down, right, and left sides of the hard coating layer having a rectangular front surface shape.

Exemplarily, the plurality of apertures are installed on at least two of four sides, i.e. up, down, right, and left sides of the hard coating layer having a rectangular front surface shape.

Also, the single sheet film filer further includes a color coating layer installed for any one of near infrared ray cut or color correction on the other surface of the base film.

According to another aspect of the present invention, there is provided a method of manufacturing a single sheet film filter including: forming a conductive layer in a specific pattern on one surface of a base film; forming a hard coating layer on the conductive layer; and laser-etching the hard coating layer at a predetermined interval so that a portion of the conductive layer is exposed in a plurality of stripe shapes at an edge region on the base film.

Exemplarily, the predetermined interval is selected in the range of 0.02 mm to 0.2 mm.

Also, the laser etching may be performed after attaching the filter to a plasma display panel through an adhesive already installed on the other surface of the filter.

In addition, the laser etching may be performed in a state of fixing the filter onto a worktable in a vacuum chamber.

Also, the method of manufacturing the single sheet film filter can further include forming a color coating layer on the other surface of the base film.

In addition, the method of manufacturing the single sheet film filter can further include forming an adhesion layer on the color coating layer.

According to another aspect of the present invention, there is provided a plasma display apparatus including: a plasma display panel; a single sheet film filter according to one aspect of the present invention arranged on a screen of the plasma display panel, and including a conductive layer exposed through a plurality of apertures in a stripe shape installed at an edge region of a hard coating layer by laser etching; and a ground terminal contacted to the conductive layer through the plurality of apertures.

Exemplarily, the ground terminal is a conductive sponge tape.

Also, the ground terminal is coupled to the plasma display panel, and is coupled to a chassis base supporting a driving circuit substrate for the plasma display panel.

With the present invention, in the single sheet film filter, ground badness is reduced, a desired contact resistance is secure, and process time for formation of the ground portion is shortened. Also, it is possible to reduce cost of the plasma display apparatus mounted with the single sheet film filter.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a specific cross-sectional view of a single sheet film filter for a plasma display apparatus according to the present invention.

FIG. 2 is a cross-sectional view illustrating the single sheet film filter according to the present invention.

FIGS. 3a and 3b are plane views of the single sheet film filter according to the present invention.

FIG. 4a is an enlarged plane view portion B of FIG. 3a.

FIG. 4b is an enlarged picture of the portion corresponding to FIG. 4a.

FIGS. 5a to 5d are process flow charts for a method of manufacturing the single sheet film filter according to the present invention.

FIG. 6 is a plane view illustrating a method of manufacturing a single sheet film filter according to another embodiment of the present invention.

FIG. 7 is a partial cross-sectional view of the plasma display apparatus adopting the single sheet film filter according to the present invention.

### DETAILED DESCRIPTION OF THE INVENTION

These and/or aspects and advantages of the invention will become apparent and more readily appreciated from the following description of the preferred embodiments, taken in conjunction with the accompanying drawings.

In the present specification, a single sheet film filter indicates a thing using one base film and forming an electromagnetic wave shielding layer, a near infrared ray cutting layer, a color correcting layer, or a combination layer thereof on this base film. The single sheet film filter has advantages that a structure is simple and cost is inexpensive, as compared to a multi-layer base film type filter using a plurality of base films and requiring long time and cost in a ground portion exposure process and a lamination process between two base films.

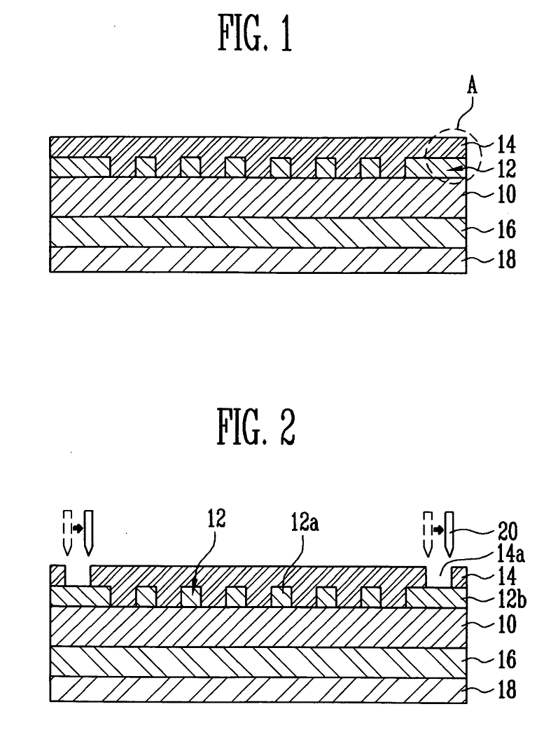

FIG. 1 is a specific cross-sectional view of a single sheet film filter accordingly to the present invention.

Referring to the single sheet film filter shown in FIG. 1, a conductive layer 12 for shielding EMI (hereinafter, referred to as an EMI shielding layer) is formed on one surface of a base film 10, and a hard coating layer 14 is formed on the EMI shielding layer 12. A near infrared ray cutting layer 16 and an adhesion layer 18 are stacked on the other surface of the base film 10. Portion A shown in a dotted line indicates a ground portion of the EMI shielding layer 12.

The single sheet film filter is attached to a front surface of a plasma display panel by the adhesion layer 18. At this time, since the EMI shielding layer 12 should be grounded, the portion A positioned at an edge region of the EMI shielding layer 12 should be exposed. However, it is difficult to remove the hard coating layer 14 on the ground portion A without impairing the EMI shielding layer 12 by half cutting. Also, the EMI shielding layer 12 is firmly coupled to the base film 10 and the hard coating layer 14. For this reason, although a precise cutting is made, it is not easy to completely remove only the hard coating layer 14 on the ground portion A with the EMI shielding layer 12 left.

Therefore, the present invention provides a method of effectively removing only the hard coating layer 14 on the ground portion A of the EMI shielding layer 12. The method includes a step exposing the ground portion A of the EMI shielding layer 12 by a laser etching process in the film filter in which the hard coating layer 14 covers the EMI shielding layer 12. Also, at the time of the laser etching process, process conditions capable of preventing impairment of the EMI shielding layer 12, and securing a desired ground resistance and at the same time, raising a process speed to reduce fabrication cost are provided.

FIG. 2 is a cross-sectional view explaining the single sheet film filter accordingly to the present invention.

Referring to FIG. 2, the ground portion 12b of the EMI shielding layer 12 of the single sheet film filter is exposed to the outside through an aperture 14a of the hard coating layer 14. The aperture 14a of the hard coating layer 14 is formed by an etching process using a laser 20.

The EMI shielding layer 12 is formed on the base film 10 through a sputtering process, and includes an effective screen portion 12a with a predetermined pattern (for example, a mesh shape) and the ground portion 12b without a pattern. Herein, the ground portion 12b includes a copper thin film. Meanwhile, the effective screen portion 12a of the EMI shielding layer 12, of course, may be also formed of a thin film without a predetermined pattern.

The hard coating layer 14 is disposed on the base film 10 to cover the whole of the EMI shielding layer 12 in order to protect the film and prevent scratch. A portion of the hard coating layer 14 positioned on the ground portion 12b is removed through the laser etching process.

At this time, a CO₂ laser may be used as the laser 20. Also, a plurality of lasers 20 may be installed on each surface of the panel.

With the present embodiment, in the single sheet film filter having a structure that the hard coating layer 14 completely covers the EMI shielding layer on the single base film 10, it is possible to effectively remove only the hard coating layer 14 on the ground portion 12b of the EMI shielding layer 12 through the laser etching process.

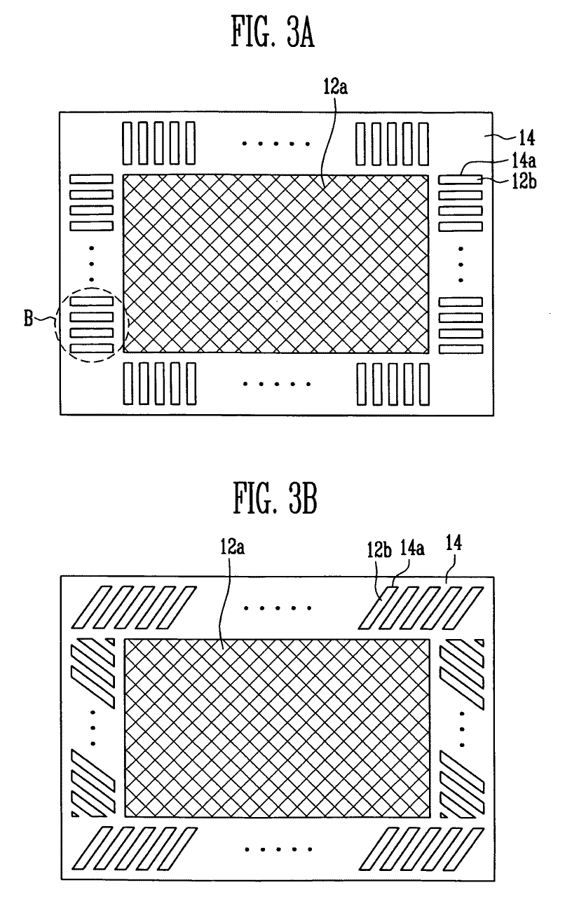

FIGS. 3a and 3b are plane views of the single sheet film filter according to the present invention.

When removing the hard coating layer 14 on the ground portion 12b through the laser etching process, a problem that the ground portion 12b is impaired by laser interference occurs. In other words, in the case where etching is performed by dense laser beams at the time of the laser etching process, a portion irradiated by overlapping laser beams is excessively etched to etch even the ground portion 12b.

Therefore, in the present embodiment, the hard coating layer 14 on the ground portion 12b is etched at a predetermined interval between the laser beams at the time of the laser etching process, as shown in FIG. 3a. The ground portion 12b is exposed in a plurality of stripe shapes through the apertures 14a in the stripe shape.

The aperture 14a formed in the hard coating layer 14 on the ground portion 12b at the time of laser etching process has the stripe shape extended in a length direction (a first direction) or a width direction (a second direction) of the panel. Of course, the aperture 14a can also have the stripe shape extended in an oblique direction having a slant with respect to the first direction or the second direction, as shown in FIG. 3b.

In the present embodiment, it may be impossible to secure the ground resistance value by the hard coating layer 14 remaining between the ground portions 12 in the stripe shape exposed through the respective apertures 14a. Therefore, in forming the apertures 14a, the laser etching process should be performed in a predetermined condition.

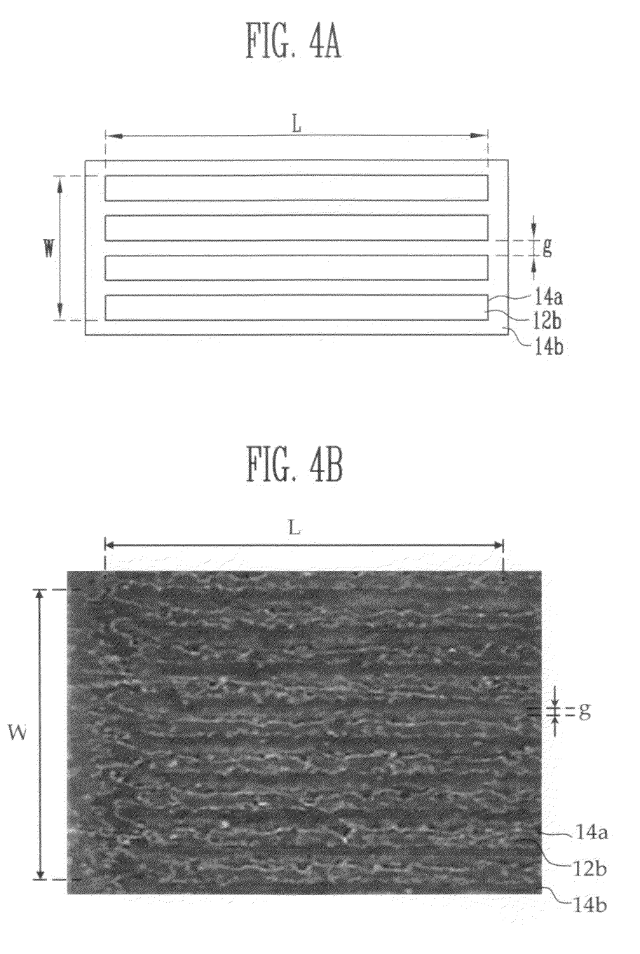

FIG. 4a is an enlarged plane view portion B of FIG. 3a, and FIG. 4b is a enlarged picture of the portion corresponding to FIG. 4a.

Referring to FIGS. 4a and 4b, the laser etching process is performed so that an interval (g) between the apertures 14a is in the range of 0.02 mm to 0.2 mm. Actually, the apertures 14a formed by the laser etching process do not have a smooth cross section, as shown in FIG. 4b. Therefore, although the gap (g) between these apertures 14a is not constant, when performing the laser etching process in consideration of the range, a desired resistance value, that is, about 0.3 Ω/cm² may be obtained. If the gap (g) is smaller than 0.02 mm, an over-etching problem that even the ground portion 12b is etched by the laser interference occurs. If the gap (g) exceeds 0.2 mm, the resistance value of the ground portion 12b increases so that ground performance is deteriorated.

Also, the range is a case where size in cross section of the laser bean is 0.2 mm horizontally and 0.2 mm vertically. It takes about 30 seconds to form four apertures 14a in an area having a length (L) of 15 cm and a width (W) of about 1.5 cm. This processing is shortened by 35 seconds, as compared to the laser etching process removing the whole of the hard coating layer 14.

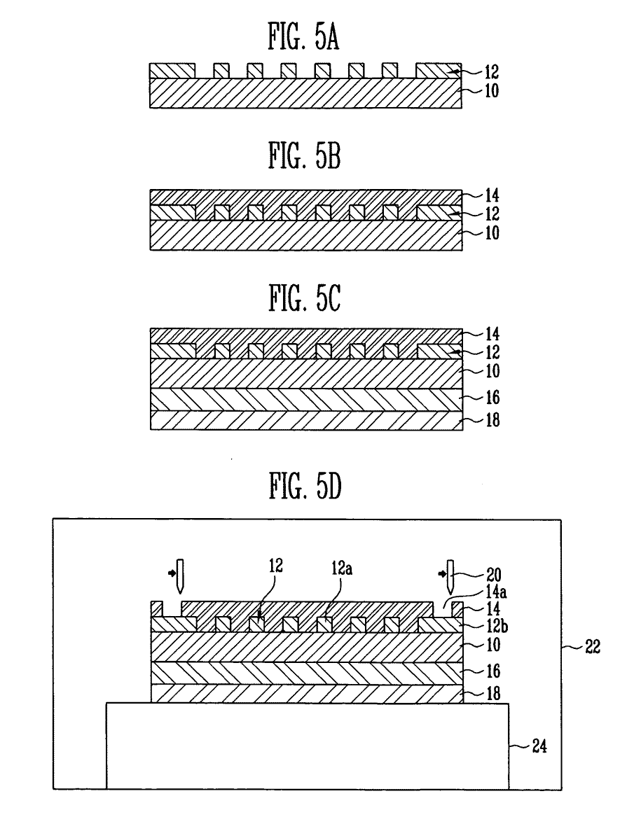

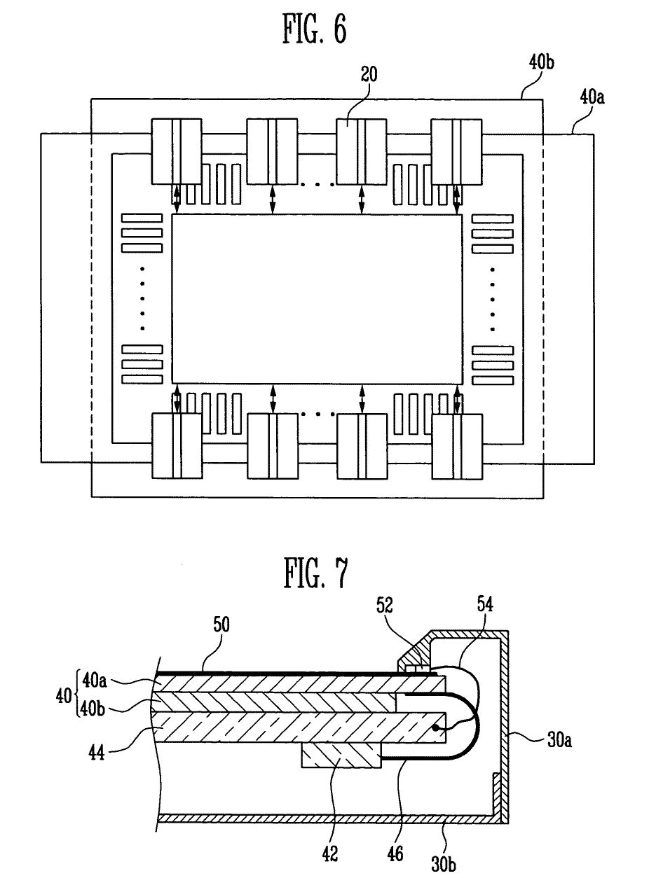

FIGS. 5a to 5d are flow charts for a method of manufacturing the single sheet film filter according to the present invention.

First, as shown in FIG. 5, the EMI shielding layer 12 in a predetermined pattern is formed on one surface of the base film 10.

The base film 10 supports the EMI shielding layer 12 and should be superior in a handling property and a chemical resistance with respect to a wet etching process in the case where it is formed by the wet etching process. The base film 10 may be fabricated using polyethersulphone (PES), polyacrylate (PAR), polyetherimide (PEI), polyethyelenen napthalate (PEN), polyethyeleneterepthalate (PET), polyphenylene sufide (PPS), polyallylate, polyimide, polycarbonate, cellulose tri-acetate (TAC), cellulose acetate propinonate (CAP), etc. Exemplarily, it may be fabricated using at least one of polycarbonate, polyethyeleneterepthalate, cellulose tri-acetate, and polyethyelenen napthalate.

The base film 10 may be colored to have a predetermined color. In this case, it is possible to adjust visible light transmittance of the whole of the film filter by adjusting a coloring condition of the base film. For example, if a dark color is imparted to the film base 10, the visible light transmittance is reduced. Therefore, it is possible to adjust a color of visible light incident to the front. Also, it is possible to impart the color to the whole of the base film 10 to have a color good for a user to visually feel, and it is also possible to impart a color in order to improve color purity of the plasma display panel. In addition, it is possible to pattern the color of the film base to correspond to each sub-pixel of the plasma display panel.

With the above-mentioned colored base film 10, a separate member (for example, a color correcting layer) for adjusting the visible light transmittance and the color of the film filter is omitted, thereby making it possible to simplify the process and reduce the cost. It is exemplary that the visible light transmittance of the base film 10 is 40% to 90%, since an overall brightness is lowered in the case where the transmittance of the colored base film is 40% or less, and a contrast improvement effect is lowered in the case where it is 90% or more.

The base film 10 has a flat panel shape, and thickness of the base film is exemplarily 50 μm to 500 μm. However, as the thickness of the base film 10 becomes thin, a scattering prevention effect is reduced at the time of panel damage, and as it becomes thick, efficiency of a lamination process is reduce. Therefore, the thickness of the base film is more exemplarily 80 μm to 400 μm.

The EMI shielding layer 12, which is a conductive layer in charge of an electromagnetic wave shielding function, may be formed using a metal thin film composed of palladium, copper, platinum, rhodium, aluminum, iron, cobalt, nickel, zinc, ruthenium, tin, tungsten, iridium, lead, gold, silver, etc, respectively or in combination. Also, it may be form using a metal oxide thin film composed of indium oxide, antimony oxide, zinc oxide, zirconium oxide, titanium oxide, magnesium oxide, aluminum oxide, metal alkoxide, indium tin oxide, ATO, etc., respectively or in combination. It is exemplary that the thickness of the EMI shielding layer 12 is 5 μm to 12 μm, in view of a surface resistance value, which is a main factor determining electromagnetic wave shielding efficiency, characteristics capable of easily implementing a fine pattern in the metal thin film, and a viewing angle of the display. In the above range, the electromagnetic wave shielding efficiency is good, and it is easy to implement line width of the fine pattern. Meanwhile, the EMI shielding layer 12 can also have a near infrared ray cutting function depending on material.

The EMI shielding layer 12 may be formed on the base film 10 by methods such as electro-plating, electroless-plating, and a combination of them, or deposition including thermal evaporation or sputtering. Also, after the EMI shielding layer 12 is prepared as the conductive layer in a film shape in which a pattern is formed, it may be laminated on the base film 10 through an adhesive.

Next, as shown in FIG. 5b, the hard coating layer 14 is formed on the base film 10 to cover the whole of the EMI shielding layer 12.

The hard coating layer 14 is installed in order to prevent scratches being generated in the panel or the film by external force in several forms. It is exemplary that the hard coating layer 14 includes polymer as a binder. As the polymer, acryl-based polymer, urethane-based polymer, epoxy-based polymer, siloxane-based polymer may be used, and ultraviolet curing resin such as oligomer may also be used. In order to improve strength, it can further include silica-based filler.

It is exemplary that thickness of the hard coating layer 14 is about 2 μm to 7 μm in order not to be excessively thick and in order to be able to obtain an expected effect. Optical characteristics of the film filter including the hard coating layer 14 is on the order of 1% to 3% in haze, on the order of 30% to 90% in the visible light transmittance, and on the order of 1% to 20% in external light reflectivity. It is exemplary that the film filter including the hard coating layer 14 is constituted to have heat resistance higher than glass transition temperature and pencil hardness of 1H to 3H.

Next, as shown in FIG. 5c, the color coating layer 16 and the adhesion layer 18 are formed on the other surface of the base film 10.

The color coating layer 16 includes a coloring matter for any one function of near infrared ray cut (NIR-cut), neon light cut (Ne-cut), cyan light cut (Cyan-cut), and color correction. The color coating layer is obtained by coating polymer film roll missing milling at least one kind coloring matter to a transparent resin or paint obtained by applying at least one kind coloring matter to resin binder and organic solvent on a transparent base. That is, the color coating layer 16 may be formed of a transparent bond containing at least one kind coloring matter. Herein, term “containing” means a state contained in the inside of the base, the film or the bond, as well as a state coated to a surface of the base or the film.

The coloring matter can be a general dye or pigment capable of absorbing light of a desired wavelength, and a kind thereof is not specially limited. For example, the kind of the coloring matter includes an organic coloring matter such as anthraquinone-based coloring matter, cyanine-based coloring matter, phthalocyanine-based coloring matter, methine-based coloring matter, azomethine-based coloring matter, ASO-based coloring matter, oxidin-base coloring matter, oxonol-based coloring matter, styryl-based coloring matter, squaryl-based coloring matter, coumarin-based coloring matter, porphyrin-based coloring matter, dibenzofuranone-based coloring matter, diketopyrrolopyrrole-based coloring matter, rhodamine-based coloring matter, xanthene-based coloring matter, pyrromethene-based coloring matter. The kind and the concentration of the coloring matter may be determined by absorption wavelength and absorption coefficient of the coloring matter, gray scale of a transparent layer, and transmission characteristics and transmittance required for the film filter.

The adhesion layer 18 is formed on the color coating layer 16, and is used when adhering the film filter to a visible surface of the plasma display panel. The adhesion layer 18 can use a transparent adhesive or bond such as ultraviolet-curable resin and/or thermoplastic resin such as acryl-based resin, silicon-based resin, urethane-based resin, polyvinyl-based resin. Exemplarily, a silicon bond such as acrylate-based resin or pressure sensitive adhesive (PSA) may be used.

Next, as shown in FIG. 5d, the hard coating layer 14 on the ground portion 12b of the EMI shielding layer 12 is removed at a predetermined interval through the laser etching process.

The laser etching process is performed in a state of fixing the film filter onto a worktable 24 installed in the inside of a vacuum chamber 22. The reason for fixing the film filter in a vacuum state is to prevent the film filter from being wrinkled or a gap from being generated between layers at the time of laser processing. As the laser 20, CO₂ laser, KrF laser, Nd:YAG laser, He—Cd laser, Ar-ion laser, etc may be used.

If using the laser etching process, it is possible to directly form the apertures 14a in the stripe shape at a predetermined interval in the hard coating layer 14 on the ground portion 12b without using a mask for an existing etching process.

Also, as a result of EMI measurement of the fabricated film filter, it has been confirmed that the film filter satisfies international standards (when the length of the vacuum chamber is 10 m) that is 30 dB or less in low-band and 37 dB or less in high-band in both length and width directions of the front surface.

FIG. 6 is a plane view explaining a method of manufacturing a single sheet film filter according to another embodiment of the present invention.

Referring to FIG. 6, in the manufacturing method of the present embodiment, a plasma display panel constituted by an upper plate 40a and a lower plate 40b is prepared. A film filter is directly formed on a front surface of the prepared panel, that is, one surface of the upper plate 40a. In other words, the manufacturing method of the present embodiment, the laser etching process is not performed after fixing the film filter onto the worktable in the vacuum chamber. Instead, after directly stacking each layer of the film filter on the front surface of the plasma display panel constituted by the upper plate 40a and the lower plate 40b, the apertures 14a is formed at the edge of the hard coating layer 14 through the laser etching process as a last process for forming film filter. Thereby, the ground portion of the EMI shielding layer is exposed to the outside through the aperture 14a.

A plurality of lasers 20 may be installed corresponding to each surface of the panel in order to process the single sheet film filter in 42 inch or 50 inch size at a time. In the present embodiment, four lasers are installed on the upper and the lower, respectively, to perform laser ground processing at a time.

With the present embodiment, when directly forming the film filter on the front surface of the panel, it is possible to directly form the apertures 14a in the stripe shape at a predetermined interval in the hard coating layer 14 on the ground portion 12b by the laser etching process. Therefore, it is possible to simplify the process and reduce the cost, as compared to the case using a separate film filter.

FIG. 7 is a partial cross-sectional view of the plasma display apparatus adopting the single sheet film filter according to the present invention.

Referring to FIG. 7, the plasma display apparatus includes a front case 30a, a rear case 30b, a plasma display panel 40, a chassis 44, a first wiring 46, a film filter 50, a ground terminal 52, and a second wiring 54. The front case 30a is formed with a window, and the rear case 30b forms an internal space together with the front case 30a. The plasma display panel 40 is disposed in the internal space, and the chassis 44 is coupled to the panel 40 and is mounted with a circuit for driving the panel 40. The first wiring 46 electrically couples the panel and a circuit substrate 42, and the film filter 50 is attached to the front surface of the panel 40. Also, the ground terminal 52 is contacted to the ground portion of the EMI shielding layer of the film filter 50, and the second wiring 54 electrically couples the ground terminal 52 to the chassis 44.

The plasma display panel 40 is constituted by the upper plate 40a and the lower plate 40b in order to form discharge space therein.

The film filter 50 indicates the single sheet film filter of the present invention in which the ground portion is exposed through the apertures in a plurality of stripe shapes formed by the laser etching, as described above.

The ground terminal 52 includes a conductive sponge. One surface of the ground terminal 52 constituted by the conductive sponge is attached to the front case 30a, and the other surface thereof is processed by a conductive material and is closely attached to the ground portion. Such a ground terminal 52 is constituted by a metal thin film in a sponge form with adhesion force, and has a shock absorbing and relieving function. In the present embodiment, even in the case where there is a little bending on due to the hard coating layer remaining after the laser ground processing, the ground terminal in the sponge form is used, thereby having a bad influence on the ground force of the EMI shielding layer.

Meanwhile, although the above-mentioned embodiments have described the case of applying the present invention to the single sheet film filter for thinness, light-weight, low-cost by way of exemplary example, the present invention is not limited to such a constitution, but is equally applicable to a film filter with two or more base films as well.

While the present invention has been described in connection with certain exemplary embodiments, it is to be understood that the invention is not limited to the disclosed embodiment, but, on the contrary, is intended to cover various modification and equivalent arrangements included within the spirit and scope of the appended claims, and-equivalents thereof.

What is claimed is:

1. A single sheet film filter, comprising:
a conductive layer for shielding EMI arranged on one surface of a transparent base film and having a ground portion at an edge region on the base film; and
a hard coating layer covering the conductive layer;
wherein the ground portion is exposed through a plurality of apertures in a stripe shape formed in the hard coating layer.

2. The single sheet film filter as recited in claim 1, wherein an average interval between the plurality of apertures is in the range of 0.02 mm to 0.2 mm.

3. The single sheet film filter as recited in claim 1, wherein the plurality of apertures include a stripe shape extended in at least one direction of a first direction, or a second direction perpendicular to the first direction, or an oblique direction different from the first and second directions on a plane.

4. The single sheet film filter as recited in claim 1, wherein the plurality of apertures are installed on at least two of four sides, i.e. up, down, right, and left sides, of the hard coating layer having a rectangular front surface shape.

5. The single sheet film filter as recited in claim 1, further comprising:
a color coating layer installed for any one of near infrared ray cut or color correction on the other surface of the base film.

6. A method of manufacturing a single sheet film filter, comprising the steps of:
forming a conductive layer in a specific pattern on one surface of a base film;
forming a hard coating layer on the conductive layer; and
laser-etching the hard coating layer at a predetermined interval so that a portion of the conductive layer is exposed in a plurality of stripe shapes at an edge region on the base film.

7. The method of manufacturing a single sheet film filter as recited in claim 6, wherein the predetermined interval is selected in the range of 0.02 mm to 0.2 mm.

8. The method of manufacturing a single sheet film filter as recited in claim 6, wherein the laser etching is performed after attaching the filter to a plasma display panel through an adhesive already installed on the other surface of the filter.

9. The method of manufacturing a single sheet film filter as recited in claim 6, wherein the laser etching is performed in a state of fixing the filter onto a worktable in a vacuum chamber.

10. The method of manufacturing a single sheet film filter as recited in claim 6, further comprising forming a color coating layer on the other surface of the base film.

11. The method of manufacturing a single sheet film filter as recited in claim 10, further including forming an adhesion layer on the color coating layer.

12. The method of manufacturing a single sheet film filter as recited in claim 6, wherein the plurality of stripe shapes are extended in at least one direction of a first direction, or a second direction perpendicular to the first direction, or an oblique direction different from the first and second directions on a plane.

13. A plasma display apparatus, comprising:
a plasma display panel;
a single sheet film filter arranged on a screen of the plasma display panel, and including a conductive layer exposed through a plurality of apertures in a stripe shape installed at an edge region of a hard coating layer by laser etching; and
a ground terminal contacted to the conductive layer through the plurality of apertures.

14. The plasma display apparatus as recited in claim 13, wherein the ground terminal is a conductive sponge tape.

15. The plasma display apparatus as recited in claim 13, wherein the ground terminal is coupled to the plasma display panel, and is coupled to a chassis base supporting a driving circuit substrate for the plasma display panel.

16. A plasma display panel having an upper plate and a lower plate, comprising:
a single sheet film filter disposed on the upper plate of the plasma display panel, and including a conductive layer exposed through a plurality of apertures in a stripe shape installed at an edge region of a hard coating layer by laser etching; and
a ground terminal contacted to the conductive layer through the plurality of apertures.
